(19) United States
(12) Patent Application Publication
(10) Pub. No.: US 2026/0083003 A1
(43) Pub. Date: Mar. 19, 2026

(54) SEMICONDUCTOR PACKAGE

(71) Applicant: Samsung Electronics Co., Ltd., Suwon-si (KR)

(72) Inventors: Keunyoung Lee, Suwon-si (KR); Taeyoung Lee, Suwon-si (KR)

(21) Appl. No.: 19/090,925

(22) Filed: Mar. 26, 2025

(30) Foreign Application Priority Data
Sep. 19, 2024 (KR) 10-2024-0126846

(51) Int. Cl. H01L 25/16; H01L 23/00; H01L 23/31; H01L 23/538; H10B 80/00

(52) U.S. Cl. CPC H10W 90/00; H10B 80/00; H10W 70/60; H10W 70/611; H10W 74/117; H10W 90/24; H10W 90/752; H10W 90/754

(57) ABSTRACT

A semiconductor package includes a package substrate, a memory controller on the package substrate and including a plurality of channels, a first semiconductor chip stack on the memory controller and including one or more first memory chips, and a second semiconductor chip stack on the package substrate, spaced apart from the first semiconductor chip stack, and including one or more second memory chips. A number of the one or more first memory chips included in the first semiconductor chip stack is different from a number of the one or more second memory chips included in the second semiconductor chip stack. A first substrate pad electrically connected to one or more first memory chips and a second substrate pad electrically connected to the one or more second memory chips are on a top surface of the package substrate.

### CROSS-REFERENCE TO RELATED APPLICATION

This application is based on and claims priority under 35 U.S. C. § 119 to Korean Patent Application No. 10-2024-0126846, filed on Sep. 19, 2024, in the Korean Intellectual Property Office, the disclosure of which is incorporated by reference herein in its entirety.

### BACKGROUND OF THE INVENTION

The inventive concept relates to a semiconductor package, and more particularly, to a semiconductor package including a plurality of semiconductor chip stacks and a controller chip.

Non-volatile memory may maintain stored data even when power thereto is cut off. Recently, storage devices each including flash-based non-volatile memory such as an embedded multi-media card (eMMC), a universal flash storage (UFS), a solid state drive (SSD), and a memory card have been widely used, and the storage devices are useful for storing or moving large amounts of data.

The storage device may be implemented as a semiconductor package including a plurality of non-volatile semiconductor chips and a controller chip. Non-volatile memory chips may be assigned to one or more channels and connected to the controller chip.

### SUMMARY OF THE INVENTION

The inventive concept relates to a semiconductor package with improved data processing efficiency and a reduced vertical height.

The problems to be solved by the technical idea of the inventive concept are not limited to the above-mentioned problems, and other problems not mentioned will be clearly understood by those skilled in the art from the following description.

According to some embodiments of the inventive concept, there is provided a semiconductor package including a package substrate, a memory controller on the package substrate and including a plurality of channels, a first semiconductor chip stack on the memory controller and including one or more first memory chips, and a second semiconductor chip stack on the package substrate, spaced apart from the first semiconductor chip stack and including one or more second memory chips. A number of the one or more first memory chips in the first semiconductor chip stack is different from s number of the one or more second memory chips in the second semiconductor chip stack. A first substrate pad electrically connected to the one or more first memory chips, and a second substrate pad electrically connected to the one or more first memory chips are on a top surface of the package substrate. The first substrate pad is associated with a first channel of the plurality of channels, and the second substrate pad is associated with a second channel of the plurality of channels.

According to some embodiments of the inventive concept, there is provided a semiconductor package including a package substrate, a memory controller on the package substrate including a plurality of channels, a plurality of semiconductor chip stacks on the package substrate, spaced apart from the memory controller, and including a first semiconductor chip stack and a third semiconductor chip stack, and a second semiconductor chip stack on the package substrate and spaced apart from the plurality of semiconductor chip stacks and the memory controller. The first semiconductor chip stack includes one or more first memory chips, the second semiconductor chip stack includes one or more second memory chips, and the third semiconductor chip stack includes one or more third memory chips. A number of the one or more first memory chips, a number of the one or more second memory chips, and a number of the one or more third memory chips are different from one another, and the number of the one or more second memory chips is greater than the sum of the number of the one or more first memory chips and the number of the one or more third memory chips. A first substrate pad electrically connected to the first semiconductor chip stack, a second substrate pad electrically connected to the second semiconductor chip stack, and a third substrate pad electrically connected to the third semiconductor chip stack are provided on a top surface of the package substrate. The first semiconductor chip stack is associated with a first channel, the second semiconductor chip stack is associated with a second channel, the third semiconductor chip stack is associated with a third channel. The first channel, the second channel, and the third channel are included in a plurality of channels included in the memory controller.

According to some embodiments of the inventive concept, there is provided a semiconductor package including a package substrate, a memory controller on the package substrate and including a plurality of channels, a first semiconductor chip stack on the package substrate and including one or more first memory chips, a second semiconductor chip stack on the package substrate and including one or more second memory chips, and a third semiconductor chip stack on the package substrate and including one or more third memory chips. A first substrate pad electrically connected to the one or more first memory chips, a second substrate pad electrically connected to the one or more second memory chips, and a third substrate pad electrically connected to the one or more third memory chips are on a top surface of the package substrate. The first substrate pad is associated with a first channel, the second substrate pad is associated with a second channel, and the third substrate pad is associated with a third channel. The first channel, the second channel, and the third channel are included in a plurality of channels included in the memory controller. A number of the one or more second memory chips included in the second semiconductor chip stack is greater than a number of the one or more first memory chips included in the first semiconductor chip stack, and a number of the one or more third memory chips included in the third semiconductor chip stack is greater than the number of the one or more second memory chips included in the second semiconductor chip stack. Throughput of the memory chip of the one or more first memory chips is greater than the throughput of the memory chip of the one or more second memory chips, which is greater than the throughput of the memory chip of the one or more third memory chips.

### BRIEF DESCRIPTION OF THE DRAWINGS

Embodiments will be more clearly understood from the following detailed description taken in conjunction with the accompanying drawings in which:

FIG. 1 is a block diagram illustrating a storage system including a semiconductor package according to embodiments;

FIG. 2 is a block diagram illustrating a host device;

FIG. 3 is a block diagram illustrating a storage device including a semiconductor package according to embodiments;

FIG. 4 is a block diagram illustrating the storage device of FIG. 1;

FIG. 5 is a cross-sectional view illustrating a semiconductor package according to embodiments;

FIG. 6 is a block diagram illustrating a storage device;

FIG. 7 is a cross-sectional view illustrating a semiconductor package according to embodiments;

FIG. 8 is a block diagram illustrating a storage device;

FIG. 9 is a cross-sectional view illustrating a semiconductor package according to embodiments;

FIG. 10 is a block diagram illustrating a storage device;

FIG. 11 is a cross-sectional view illustrating a semiconductor package according to embodiments;

FIG. 12 is a block diagram illustrating a storage device;

FIG. 13 is a cross-sectional view illustrating a semiconductor package according to embodiments;

FIG. 14 is a block diagram illustrating a storage device; and

FIG. 15 is a cross-sectional view illustrating a semiconductor package according to embodiments.

### DETAILED DESCRIPTION OF THE EMBODIMENTS

Hereinafter, embodiments of the inventive concept will be described in detail with reference to the accompanying drawings.

Embodiments of the inventive concept are provided to more fully explain the technical idea of the inventive concept to those skilled in the art. The following embodiments may be modified into various other forms, and the scope of the technical idea of the inventive concept is not limited to the following embodiments. Rather, these embodiments are provided to make the present disclosure more faithful and complete and to fully convey the technical idea of the inventive concept to those skilled in the art. In addition, in the drawings, a thickness or size of each layer may be exaggerated for convenience and clarity of explanation. A portion unrelated to the description may be omitted in order to clearly describe the present disclosure, and the same or similar components may be denoted by the same reference numeral throughout the present specification unless clearly described otherwise.

In the current specification, a first direction may refer to an X direction, a second direction may refer to a Y direction, and the first direction and the second direction may be perpendicular to each other. A third direction may be a Z direction, and the third direction may be perpendicular to each of the first direction and the second direction. A horizontal plane or plane refers to an X-Y plane. A top surface of a specific object refers to a surface positioned in a positive third direction with respect to the specific object, and a bottom surface of a specific object refers to a surface positioned in a negative third direction with respect to the specific object. As used herein, the term “and/or” includes any and all combinations of one or more of the associated listed items.

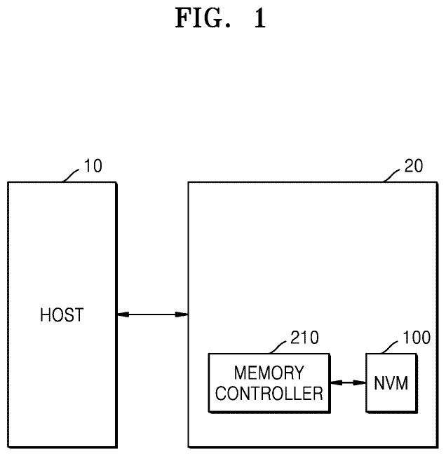

FIG. 1 is a block diagram illustrating a storage system including a semiconductor package according to embodiments.

Referring to FIG. 1, the storage system may include a host device 10 and a storage device 20.

In embodiments, the storage device 20 may be implemented as internal memory built in an electronic device, and may be, for example, an embedded universal flash storage (UFS) memory device or an embedded multi-media card (eMMC). In an embodiment, the storage device 20 may be implemented as external memory that is removable from the electronic device, and may be, for example, a UFS memory card, a compact flash (CF) card, a secure digital (SD) card, a micro secure digital (micro-SD) card, a mini secure digital (mini-SD) card, an extreme digital (xD) card, or memory stick.

The host device 10 may provide logical addresses and commands to the storage device 20. During a write operation, the host device 10 may request the storage device 20 to program data to be written to a storage area of non-volatile memory 100 corresponding to a logical address. During a read operation, the host device 10 may request the storage device 20 for data to be read from the storage area of the non-volatile memory 100 corresponding to the logical address.

The storage device 20 may include a memory controller 210 and the non-volatile memory 100. The storage device 20 may correspond to a semiconductor package 1 according to embodiments. The semiconductor package 1 is described in detail below.

The memory controller 210 may generally control the storage device 20. Data read from the non-volatile memory 100 may be provided to the host device 10, and data provided from the host device 10 may be written to the non-volatile memory 100.

The memory controller 210 may control the non-volatile memory 100 to read data stored in the non-volatile memory 100 or to write data to the non-volatile memory 100, in response to a write/read request from the host device 10.

Specifically, the memory controller 210 may control write, read, and erase operations of the non-volatile memory 100 by providing addresses, commands, and control signals to the non-volatile memory 100. In addition, data to be written and read data may be transmitted and received between the memory controller 210 and the non-volatile memory 100.

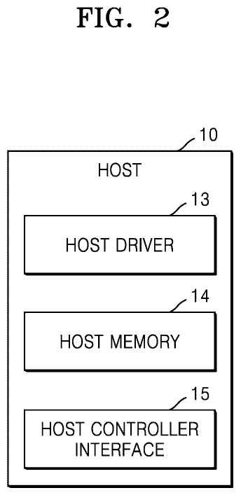

FIG. 2 is a block diagram illustrating the host device 10.

Referring to FIG. 2, the host device 10 may include a host driver 13, host memory 14, and a host controller interface 15. In the current specification, the host device 10 may be a UFS host according to the UFS standard.

In some embodiments, the host driver 13 may convert an input/output request generated by an application into a UFS command defined by the UFS standard and may transmit the UFS command to the host controller interface 15. One input/output request may be converted into a plurality of UFS commands. The input/output request may be referred to as a task request. The UFS command may be a concept including UFS protocol information units (UPIU) according to the UFS standard. The UFS command may basically be a command defined by the small computer system interface (SCSI) standard, but may also be a command exclusive to the UFS standard.

The host controller interface 15 may transmit the UFS command converted by a UFS driver to the storage device 20. Although the host memory 14 is illustrated as being separate from the host controller interface 15 in FIG. 2, in some embodiments, the host memory 14 may be included in the host controller interface 15. The host controller interface 15 may control the host memory 14 to copy data from a normal region of the host memory 14 to a cache region of the host memory 14. The host controller interface 15 may transmit the logical address (for example, a logical block address (LBA) to the storage device 20.

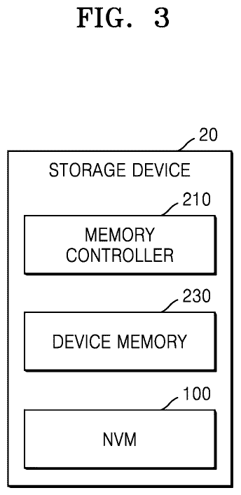

FIG. 3 is a block diagram illustrating the storage device 20 including the semiconductor package 1 according to embodiments. FIG. 3 may be described with reference to FIG. 1.

Referring to FIG. 3, the storage device 20 may include the memory controller 210, device memory 230, and the non-volatile memory 100. Descriptions of the memory controller 210 and the non-volatile memory 100 may be omitted because the memory controller 210 and the non-volatile memory 100 have been described above with reference to FIG. 1.

The device memory 230 may temporarily store data to be written to the non-volatile memory 100 or data read from the non-volatile memory 100. The device memory 230 may include static random access memory (SRAM) or dynamic random access memory (DRAM).

The non-volatile memory 100 may include a memory cell array. For example, a plurality of memory cells included in the memory cell array may be non-volatile memory cells maintaining stored data even when supplied power thereto is cut off. Specifically, when the plurality of memory cells are non-volatile memory cells, the non-volatile memory 100 may include electrically erasable and programmable read-only memory (EEPROM), flash memory, phase-change random access memory (PRAM), resistive random access memory (RRAM), nano-floating gate memory (NFGM), polymer random access memory (PoRAM), magnetic random access memory (MRAM), or ferroelectric random access memory (FeRAM). Hereinafter, embodiments will be described in detail by taking a case in which the plurality of memory cells are NAND flash memory cells as an example. However, the inventive concept is n ot limited thereto.

The memory cell array may include a plurality of memory blocks, and each memory block may have a planar structure or a three-dimensional structure. The memory cell array may include at least one of a single-level cell block including single-level cells (SLC), a multi-level cell block including multi-level cells (MLC), a triple-level cell block including triple-level cells (TLC), and a quad-level cell block including quad-level cells (TLC).

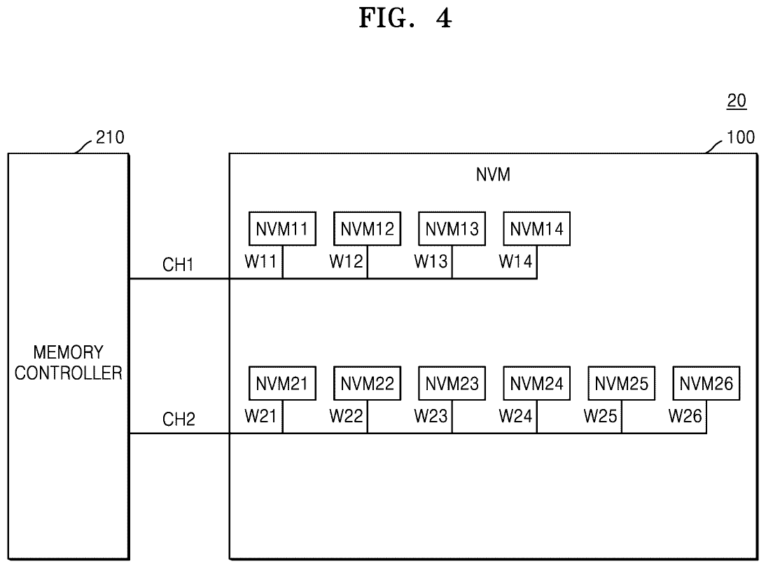

FIG. 4 is a block diagram illustrating the storage device 20 of FIG. 1. FIG. 4 may be described with reference to FIG. 3.

Referring to FIG. 4, the storage device 20 may include the memory controller 210 and the non-volatile memory 100. As described above, the storage device 20 may include the semiconductor package 1 according to embodiments. In the current specification, description will be given by taking a case in which the storage device 20 corresponds to the semiconductor package 1 as an example. However, the inventive concept is not limited thereto. That is, a plurality of semiconductor packages 1 may be provided in the storage device 20.

The storage device 20 may include one or more non-volatile memory devices and may store data in storage regions according to the possibility of data merging. As described above, the storage device 20 may be a UFS and may include a UFS of which region is divided according to the possibility of data merging (a zoned UFS). The memory controller 210 may support the zoned UFS. The zoned UFS may efficiently manage data in the storage device 20 and optimize performance. The zoned UFS uses a method of dividing the storage device into several zones and sequentially recording data in each zone when storing data. The zoned UFS may follow the Zoned Storage for UFS (JESD220-5) of the Joint Electron Device Engineering Council (JEDEC).

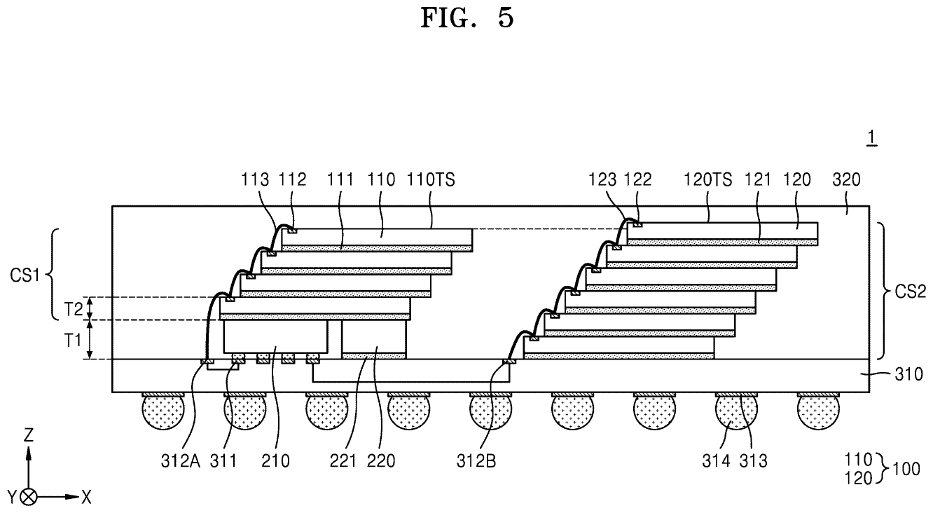

The semiconductor package 1, which is described below and corresponds to the storage device 20, includes a plurality of channels, and memory chips may be unevenly assigned to the plurality of channels. Due to uneven arrangement of memory chips, throughput per chip of each memory chip may vary. By integrating the uneven arrangement of memory chips per channel and the zoned UFS, the semiconductor package 1 may store data in different zones according to a frequency of data use and a purpose of data use. For example, in the semiconductor package 1 of FIG. 5, as described below, throughput per chip of a first memory chip 110 belonging to a first channel CH1 may be greater than throughput per chip of a second memory chip 120 belonging to a second channel CH2. By storing data with a higher frequency of use in the first memory chip 110 than in the second memory chip 120, a storage and read speed of data may be increased, and management efficiency of the non-volatile memory 100 may be improved.

The storage device 20 may support the plurality of channels, and the non-volatile memory 100 and the memory controller 210 may be connected to each other through the plurality of channels. For example, the storage device 20 may include two channels CH1 and CH2, and the non-volatile memory 100 and the memory controller 210 may be connected to each other through the two channels CH1 and CH2.

The non-volatile memory 100 may include a plurality of non-volatile memory devices. Each of the plurality of non-volatile memory devices may be connected to one of the plurality of channels through a corresponding way. For example, non-volatile memory devices NVM11, NVM12, NVM13, and NVM14 may be connected to the first channel CH1 through ways W11, W12, W13, and W14, and non-volatile memory devices NVM21, NVM22, NVM23, NVM24, NVM25, and NVM26 may be connected to the second channel CH2 through ways W21, W22, W23, W24, W25, and W26. In embodiments, each of the plurality of non-volatile memory devices may be implemented as an arbitrary memory unit that may operate according to an individual command from the memory controller 210. For example, each of the plurality of non-volatile memory devices may be implemented as a chip or a die. However, the inventive concept is not limited thereto.

The memory controller 210 may transmit and receive signals to and from the non-volatile memory 100 through the plurality of channels. For example, the memory controller 210 may transmit commands, addresses, and data to the non-volatile memory 100 through the first and second channels CH1 and CH2 or may receive data from the non-volatile memory 100.

The memory controller 210 may select one of the non-volatile memory devices connected to the corresponding channel through each channel and may transmit and receive signals to and from the selected non-volatile memory device. For example, the memory controller 210 may select the non-volatile memory device NVM11 from the non-volatile memory devices NVM11, NVM12, NVM13, and NVM14 connected to the first channel CH1. The memory controller 210 may transmit a command, an address, and data to the selected non-volatile memory device NVM11 through the first channel CH1 or may receive data from the selected non-volatile memory device NVM11.

The memory controller 210 may transmit and receive signals to and from the non-volatile memory 100 in parallel through different channels. For example, the memory controller 210 may transmit another command to the non-volatile memory 100 through the second channel CH2 while transmitting a command to the non-volatile memory 100 through the first channel CH1. For example, the memory controller 210 may receive other data from the non-volatile memory 100 through the second channel CH2 while receiving data from the non-volatile memory 100 through the first channel CH1.

The memory controller 210 may control the overall operation of the non-volatile memory 100. The memory controller 210 may control each of the non-volatile memory devices NVM11, NVM12, NVM13, and NVM14 and NVM21, NVM22, NVM23, NVM24, NVM25, andNVM26 connected to the first and second channels CH1 to CH2 by transmitting signals to the first and second channels CH1 and CH2. For example, the memory controller 210 may control one selected from the non-volatile memory devices NVM11, NVM12, NVM13, and NVM14 by transmitting a command and an address to the first channel CH1.

Each of the non-volatile memory devices NVM11, NVM12, NVM13, and NVM14 and NVM21, NVM22, NVM23, NVM24, NVM25, and NVM26 may operate under control by the memory controller 210. For example, the non-volatile memory device NVM11 may program data according to a command, an address, and data provided to the first channel CH1. For example, the non-volatile memory device NVM21 may read data according to a command and an address provided to the second channel CH2 and may transmit the read data to the memory controller 210.

In the current specification, the storage device 20 may correspond to the semiconductor package 1 according to embodiments. In the current specification, the semiconductor package 1 is described in correspondence to the storage device 20. However, the inventive concept is not li mited thereto. That is, the storage device 20 may include a plurality of semiconductor packages 1.

FIG. 5 is a cross-sectional view illustrating the semiconductor package 1 according to embodiments. FIG. 5 may be described with reference to FIG. 4.

Referring to FIG. 5, the semiconductor package 1 may include a package substrate 310, a memory controller 210 provided on the package substrate 310, a spacer 220 provided on the package substrate 310 and laterally apart from the memory controller 210, a first semiconductor chip stack CS1 provided on the memory controller 210 and the spacer 220, a second semiconductor chip stack CS2 provided on the package substrate 310 and laterally apart from the first semiconductor chip stack CS1, and an encapsulant 320.

A first substrate pad 312A, a second substrate pad 312B, and a plurality of first substrate chip pads 311 may be provided on a top surface of the package substrate 310. External connection pads 313 and external connection terminals 314 provided on the external connection pads 313 may be provided on a bottom surface of the package substrate 310. The semiconductor package 1 may be connected to an external electronic device, for example, a printed circuit board (PCB) through the external connection terminals 314. The package substrate 310 may be, for example, a PCB or a redistribution structure.

In embodiments, the package substrate 310 may be a PCB. The package substrate 310 may include a base layer, and the base layer may include a plurality of stacked sub-base layers. Top and bottom surfaces of the base layer may be covered with or overlapped by a solder resist layer. The first substrate pad 312A, the second substrate pad 312B, the plurality of first substrate chip pads 311, and the external connection pads 313 may be exposed, or not covered with or not overlapped by the solder resist layer, at top and bottom surfaces of the package substrate 310.

In some embodiments, the base layer may include at least one material selected from phenol resin, epoxy resin, and/or polyimide. For example, the base layer may include at least one material selected from flame retardant 4 (FR4), tetrafunctional epoxy, polyphenylene ether, epoxy/polyphenylene oxide, bismaleimide triazine (BT), thermount, cyanate ester, polyimide, and/or a liquid crystal polymer.

When the package substrate 310 is a redistribution structure, the package substrate 310 may include a plurality of redistribution insulating layers and a redistribution pattern provided in each of the plurality of redistribution insulating layers. The redistribution pattern may include a plurality of redistribution line patterns and a plurality of redistribution via patterns. The plurality of redistribution line patterns may be interposed among the plurality of redistribution insulating layers, and the plurality of redistribution via patterns may pass through the plurality of redistribution insulating layers to connect the plurality of redistribution line patterns to one another.

In some embodiments, the redistribution insulating layer may include an insulating material, for example, a photoimagable dielectric (PID) resin. In this case, the redistribution insulating layer may further include an inorganic filler. The redistribution pattern may include a conductive material, for example, copper (Cu), aluminum (Al), silver (Ag), tin (Sn), gold (Au), nickel (Ni), lead (Pb), titanium (Ti), or an alloy thereof.

In FIG. 5, electrical connection between the first substrate pad 312A, the second substrate pad 312B, and the plurality of first substrate chip pads 311 of the package substrate 310 is schematically illustrated. The first substrate pad 312A, the second substrate pad 312B, the plurality of first substrate chip pads 311, and the plurality of external connection pads 313 may be electrically connected to one another but are not separately indicated for visibility in the drawing. Hereinafter, in the current specification, indications of electrical connections to the plurality of external connection pads 313 are omitted for visibility of the drawings.

The memory controller 210 may be provided on the package substrate 310. A plurality of connection terminals may be provided on a bottom surface of the memory controller 210. Electrical connections to the plurality of external connection pads 313 may be performed through the plurality of first substrate chip pads 311 provided on the top surface of the package substrate 310 and the plurality of connection terminals provided on the bottom surface of the memory controller 210.

The memory controller 210 may include a plurality of various types of individual devices. For example, the memory controller 210 may include a metal-oxide-semiconductor field effect transistor (MOSFET) such as a complementary metal-oxide semiconductor (CMOS) transistor, system large scale integration (LSI), an active device, and/or a passive device.

As described above with reference to FIGS. 1 to 4, the memory controller 210 may generally control the storage device 20. The memory controller 210 may control the non-volatile memory 100 to read data stored in the non-volatile memory 100 or to write data to the non-volatile memory 100, in response to a write/read request from the host device 10. The non-volatile memory 100 and the memory controller 210 may be connected to each other through the plurality of channels.

The spacer 220 may be laterally apart from the memory controller 210 but may be provided on the package substrate 310 to be adjacent to the memory controller 210. The spacer 220 may include a dummy chip having a vertical thickness substantially the same as that of the memory controller 210. The spacer 220 may include a PCB, a metal plate, a plastic plate, or a semiconductor substrate.

The first semiconductor chip stack CS1 may include one or more first memory chips 110. For example, as illustrated in FIG. 5, the first semiconductor chip stack CS1 may include four first memory chips 110.

The plurality of first memory chips 110 may be stacked in steps. That is, the first memory chip 110 may be offset in a specific direction than the first memory chip 110 located thereunder to be arranged on the first memory chip 110 located thereunder. For example, as illustrated in FIG. 5, the first memory chip 110 arranged on the first memory chip 110 located thereunder may be offset in a positive first direction (+X direction) so that the first memory chip 110 may be arranged immediately on the first memory chip 110 located thereunder.

A plurality of first chip pads 112 may be respectively provided on parts of top surfaces of the plurality of first memory chips 110 exposed due to the offsets of the plurality of first memory chips 110. That is, the plurality of first chip pads 112 may be arranged on the exposed parts of the top surfaces of the plurality of first memory chips 110 stacked in steps, respectively. The first chip pad 112 may be exposed from a passivation layer provided on the top surface of the first memory chip 110. Some of the plurality of first chip pads 112 may be data pads for transmitting data signals.

One end of a first conductive wire 113 may be connected to the first chip pad 112 of the first memory chip 110. The other end of the first conductive wire 113 may be connected to the first substrate pad 312A provided on the package substrate 310. In addition, both ends of the first conductive wire 113 may be connected to first chip pads 112 of different first memory chips 110, respectively. Because the first semiconductor chip stack CS1 may be included in or associated with the first channel CH1, the first memory chip 110, the first chip pad 112, and the first substrate pad 312A may each correspond to part of the first channel CH1.

The first memory chip 110 may include a first semiconductor substrate. The first semiconductor substrate may include, for example, silicon (Si). Alternatively, the first semiconductor substrate may include a semiconductor element such as germanium (Ge), or a compound semiconductor such as silicon carbide (SiC), gallium arsenide (GaAs), indium arsenide (InAs), or indium phosphide (InP). Alternatively, the first semiconductor substrate may have a silicon-on-insulator (SOI) structure. For example, the first semiconductor substrate may include a buried oxide (BOX) layer. The first semiconductor substrate may include a conductive region, for example, a well doped with impurities. The first semiconductor substrate may have various device isolation structures such as a shallow trench isolation (STI) structure.

The first semiconductor substrate may have a first active surface and a first inactive surface opposite to the first active surface. The first inactive surface may be referred to as a rear surface of the first substrate. For example, the first active surface may be adjacent to a top surface of the first memory chip 110, and the first inactive surface may be a bottom surface of the first memory chip 110.

For example, the first memory chip 110 may be a memory semiconductor chip. In some embodiments, the first memory chip 110 may include a memory semiconductor device and the memory semiconductor device may include a non-volatile memory semiconductor device such as flash memory, PRAM, MRAM, FeRAM, or RRAM. The flash memory may be, for example, V-NAND flash memory.

A first die adhesive film 111 may be provided on the bottom surface of the first memory chip 110, and the first die adhesive film 111 may be attached to a structure thereunder. For example, the lowermost first memory chip 110 among the plurality of first memory chips 110 may include the first die adhesive film 111 between the first memory chip 110 and the memory controller 210. The first die adhesive film 111 may be provided on a top surface of the memory controller 210 and a top surface of the spacer 220. First die adhesive films 111 may be provided among the remainder of the plurality of first memory chips 110.

The first die adhesive film 111 may include, for example, an inorganic adhesive or a polymer adhesive. The polymer adhesive may include, for example, a thermosetting polymer or a thermoplastic polymer.

The second semiconductor chip stack CS2 may be provided on the package substrate 310 and laterally apart from the first semiconductor chip stack CS1 and the memory controller 210. The second semiconductor chip stack CS2 may include one or more second memory chips 120. For example, as illustrated in FIG. 5, the second semiconductor chip stack CS2 may include six second memory chips 120.

The plurality of second memory chips 120 may be stacked in steps. A plurality of second chip pads 122 may be provided on parts of top surfaces of the plurality of second memory chips 120 exposed due to offsets of the plurality of second memory chips 120, respectively. One end of a second conductive wire 123 may be connected to the second chip pad 122 of the second memory chip 120. The other end of the second conductive wire 123 may be connected to the second substrate pad 312B provided on the package substrate 310. In addition, both ends of the second conductive wire 123 may be connected to second chip pads 122 of different second memory chips 120, respectively.

Because the second semiconductor chip stack CS2 may be included in the second channel CH2, the second memory chip 120, the second chip pad 122, and the second substrate pad 312B may each correspond to part of the second channel CH2.

The second memory chip 120 may include a first semiconductor substrate. The first semiconductor substrate may include, for example, silicon (Si). The first semiconductor substrate may have a first active surface and a first inactive surface opposite to the first active surface.

For example, the first memory chip 110 may be a memory semiconductor chip. In some embodiments, the first memory chip 110 may include a memory semiconductor device, and the memory semiconductor device may be a non-volatile memory semiconductor device. A second die adhesive film 121 may be provided on a bottom surface of the second memory chip 120. Omitted description of the second semiconductor chip stack CS2 may be substantially the same as description of the first semiconductor chip stack CS1.

The encapsulant 320 may surround the first semiconductor chip stack CS1, the second semiconductor chip stack CS2, and the memory controller 210 on the package substrate 310. Side surfaces of the encapsulant 320 may be vertically aligned or flush with side surfaces of the package substrate 310. The encapsulant 320 may include, for example, an epoxy molding compound (EMC) or a polymer material.

A plurality of non-volatile memories 100 may be assigned to the first channel CH1 and the second channel CH2, as illustrated in FIG. 4. The memory controller 210 and the plurality of non-volatile memories 100 may transmit and receive signals including data to and from the plurality of non-volatile memories 100 through the first channel CH1 and the second channel CH2. The plurality of non-volatile memories 100 may include the first memory chip 110 and the second memory chip 120.

For example, the first semiconductor chip stack CS1 may be included in the first channel CH1. The first chip pad 112 provided in the first memory chip 110 may be included in the first channel CH1. In addition, the first substrate pad 312A electrically connected to the first chip pad 112 through the first conductive wire 113 may be included in the first channel CH1. The first substrate pad 312A may exchange signals with the memory controller 210 through wiring provided on the package substrate 310.

For example, the second semiconductor chip stack CS2 may be included in the second channel CH2. The second chip pad 122 provided in the second memory chip 120 and the second substrate pad 312B electrically connected to the second chip pad 122 through the second conductive wire 123 may be included in the second channel CH2. The second substrate pad 312B may exchange signals with the memory controller 210 through wiring provided on the package substrate 310.

In the semiconductor package 1 according to embodiments, the number of memory chips assigned to each channel may be unequal. For example, in the semiconductor package 1, four first memory chips 110 may be included in the first channel CH1, and six second memory chips 120 may be included in the second channel CH2. The first memory chip 110 and the second memory chip 120 included in the plurality of non-volatile memories 100 are physically assigned to each channel. Accordingly, the channels of the first and second memory chips 110 and 120 included in the plurality of non-volatile memories 100 may not be dynamically changed. That is, the first and second memory chips 110 and 120 may be exclusively associated with the first and second channel CH1 and CH2 respectively and may not be associated with any other channel.

Data requiring a relatively high-speed operation may use the first channel CH1, and data requiring a relatively low-speed operation may use the second channel CH2. A bandwidth per channel may be substantially similar for each channel. For example, because the maximum bandwidth per channel is 11.6 Gbps in UFS 4.0, each channel may have a bandwidth of up to 11.6 Gbps. Accordingly, the throughput per chip of the first memory chip 110 belonging to the first channel CH1 including four first memory chips 110 may be greater than the throughput per chip of the second memory chip 120 belonging to the second channel CH2 including six second memory chips 120.

The memory controller 210 may determine whether data requires a high-speed operation to selectively distribute the data to the first channel CH1 or the second channel CH2. Because the throughput per chip of the first memory chip 110 included in the first channel CH1 is greater than the throughput per chip of the second memory chip 120 included in the second channel CH2, the memory controller 210 may assign the data requiring a high-speed operation to the first channel CH1. That is, in the semiconductor package 1 according to embodiments, data processing efficiency may be improved through channels in which memory chips are unevenly arranged, and data may be effectively stored in and read from the plurality of non-volatile memories 100. However, in the semiconductor package 1 according to an embodiment, the number of channels and the specific number of memory chips assigned to the channels are not limited by the previous example, except for the uneven arrangement of memory chips.

A first thickness T1 that is a vertical thickness of the memory controller 210 from the top surface of the package substrate 310 may be, for example, in a range of 1 to 2 times a second thickness T2. The second thickness T2 may be a vertical thickness including the first die adhesive film 111 of the first memory chip 110. However, the second thickness T2 is not limited to the vertical thickness of the first memory chip 110 and may be a vertical thickness of another memory chip included in the semiconductor package 1. For example, the second thickness T2 may be set to a vertical thickness of the second memory chip 120.

A difference between a vertical level of a first uppermost surface 110TS of the first semiconductor chip stack CS1 with respect to the top surface of the package substrate 310 and a vertical level of a second uppermost surface 120TS of the second semiconductor chip stack CS2 with respect to the top surface of the package substrate 310 may be less than the first thickness T1. In the current specification, a case in which memory chips included in different semiconductor chip stacks all have substantially the same vertical thickness is described as an example. However, the inventive concept is not limited thereto.

For example, when the second thickness T2 of the memory controller 210 is one times the first thickness T1 of the first memory chip 110 so that the first thickness T1 is equal to the second thickness T2, a difference between the vertical level of the first uppermost surface 110TS and the vertical level of the second uppermost surface 120TS may correspond to the first thickness T1. At the same time, a vertical level of the highest memory chip from the top surface of the package substrate 310 may be the second uppermost surface 120TS.

For example, when the second thickness T2 of the memory controller 210 is two times the first thickness T1 of the first memory chip 110, the vertical level of the first uppermost surface 110TS may be substantially the same as the vertical level of the second uppermost surface 120TS.

As an example other than the inventive concept for comparison with the semiconductor package 1 according to embodiments, for example, when the number of memory chips per channel is equal, it may be assumed that each of the first semiconductor chip stack and the second semiconductor chip stack includes five memory chips. That is, when the first semiconductor chip stack is provided on the memory controller, the vertical level of the top of the first semiconductor chip stack and the vertical level of the top of the second semiconductor chip stack may differ by the height of the memory controller.

A vertical height of the semiconductor package 1 according to embodiments may be reduced through the uneven arrangement of memory chips. For example, as illustrated in FIG. 5, four first memory chips 110 may be located on the memory controller 210, and six second memory chips 120 may be located on the package substrate 310.

For example, in a semiconductor package including 10 memory chips, when a chip stack including 5 memory chips on a memory controller and a chip stack including 5 memory chips on a package substrate are provided, a difference in height between the tops of the chip stacks may be equal to the vertical thickness of the memory controller as described above. In addition, the vertical level of the top of the memory chip from the package substrate may correspond to the sum of the vertical thickness of the memory controller and the vertical thickness of the five memory chips.

As described above, when the vertical thicknesses of the first memory chip 110 and the second memory chip 120 are substantially the same, and the first thickness T1 of the memory controller 210 is in a range of 1 to 2 times the second thickness T2 of the first memory chip 110, a difference in vertical level between the first uppermost surface 110TS and the second uppermost surface 120TS may be equal to the second thickness T2 or less.

The vertical level of the highest memory chip from the top surface of the package substrate 310 may be the vertical level of the first uppermost surface 110TS that is a vertical height of the first semiconductor chip stack CS1 including the memory controller 210 and the four first memory chips 110, or the vertical level of the second uppermost surface 120TS of the second semiconductor chip stack CS2 including the six second memory chips 120. The first uppermost surface 110TS may refer to a top surface of the uppermost first memory chip 110 of the first memory chips 110 provided in the first semiconductor chip stack CS1, and the second uppermost surface 120TS may refer to a top surface of the uppermost second memory chip 120 of the second memory chips 120 provided in the second semiconductor chip stack CS2.

As described above, a vertical thickness of the semiconductor package 1 according to embodiments may be reduced in a case in which the memory chips are unevenly distributed to the plurality of chip stacks compared to a case in which the same number of memory chips are included and the memory chips are evenly distributed to the plurality of chip stacks.

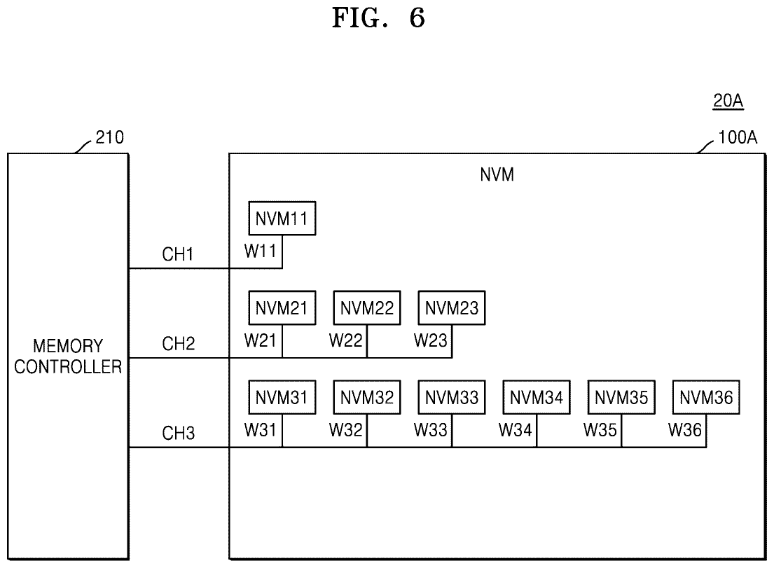

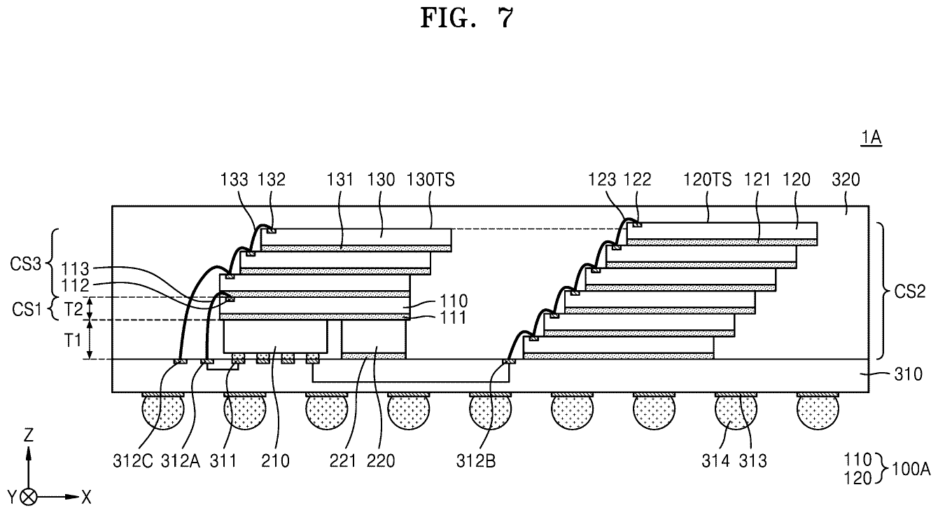

FIG. 6 is a block diagram illustrating a storage device 20A. FIG. 7 is a cross-sectional view illustrating a semiconductor package 1A according to embodiments.

Referring to FIG. 6, the storage device 20A may include a memory controller 210 and non-volatile memory 100A. The storage device 20A may support a plurality of channels, and the non-volatile memory 100A and the memory controller 210 may be connected to each other through the plurality of channels. For example, the storage device 20A may include three channels CH1, CH2, and CH3, and the non-volatile memory 100A and the memory controller 210 may be connected to each other through the three channels CH1, CH2, and CH3. The storage device 20A may correspond to the semiconductor package 1A according to embodiments.

The non-volatile memory 100A may include a plurality of non-volatile memory devices. Each of the plurality of non-volatile memory devices may be connected to one of the plurality of channels through a corresponding way. For example, a non-volatile memory device NVM11 may be connected to the first channel CH1 through a way W11, non-volatile memory devices NVM21, NVM22, and NVM23 may be connected to the second channel CH2 through ways W21, W22, and W23 respectively, and non-volatile memory devices NVM31, NVM32, NVM33, NVM34, NVM35, and NVM36 may be connected to the third channel CH3 through ways W31, W32, W33, W34, W35, and W36 respectively. In embodiments, each of the plurality of non-volatile memory devices may be implemented as an arbitrary memory unit that may operate according to an individual command from the memory controller 210.

The memory controller 210 may transmit and receive signals to and from the non-volatile memory 100 through the plurality of channels. For example, the memory controller 210 may transmit commands, addresses, and data to the non-volatile memory 100A through the channels CH1, CH2, and CH3, or may receive data from the non-volatile memory 100A.

The memory controller 210 may select one of the non-volatile memory devices connected to the corresponding channel through each channel and may transmit and receive signals to and from the selected non-volatile memory device. The memory controller 210 may transmit and receive signals to and from the non-volatile memory 100A in parallel through different channels. The memory controller 210 may control the overall operation of the non-volatile memory 100A, and each of the non-volatile memory devices NVM11, NVM21, NVM22, and NVM23, and NVM31, NVM32, NVM33, NVM34, NVM35, and NVM36 may operate under control of the memory controller 210.

Referring to FIG. 7, the semiconductor package 1A may include a package substrate 310, a memory controller 210 provided on the package substrate 310, a spacer 220 provided on the package substrate 310 and laterally apart from the memory controller 210, a first semiconductor chip stack CS1 provided on the memory controller 210 and the spacer 220, a third semiconductor chip stack CS3 provided on the first semiconductor chip stack CS1, a second semiconductor chip stack CS2 provided on the package substrate 310 and laterally apart from the first semiconductor chip stack CS1, and an encapsulant 320.

A first substrate pad 312A, a second substrate pad 312B, a third substrate pad 312C, and a plurality of first substrate chip pads 311 may be provided on a top surface of the package substrate 310.

The first semiconductor chip stack CS1 may include one or more first memory chips 110. For example, as illustrated in FIG. 7, the first semiconductor chip stack CS1 may include one first memory chip 110. A first chip pad 112 may be provided on a top surface of the first memory chip 110.

One end of a first conductive wire 113 may be connected to the first chip pad 112 of the first memory chip 110. The other end of the first conductive wire 113 may be connected to the first substrate pad 312A provided on the package substrate 310. In addition, both ends of the first conductive wire 113 may be connected to first chip pads 112 of different first memory chips 110, respectively. For example, the first semiconductor chip stack CS1 may be included in the first channel CH1. The first chip pad 112 provided in the first memory chip 110 may be included in the first channel CH1. The first substrate pad 312A may exchange signals with the memory controller 210 through wiring provided on the package substrate 310.

The second semiconductor chip stack CS2 may be provided on the package substrate 310 and laterally apart from the first semiconductor chip stack CS1 and the memory controller 210. The second semiconductor chip stack CS2 may include one or more second memory chips 120. For example, as illustrated in FIG. 7, the second semiconductor chip stack CS2 may include six second memory chips 120. The plurality of second memory chips 120 may be stacked in steps.

One end of a second conductive wire 123 may be connected to the second chip pad 122 of the second memory chip 120. The other end of the second conductive wire 123 may be connected to the second substrate pad 312B provided on the package substrate 310. In addition, both ends of the second conductive wire 123 may be connected to second chip pads 122 of different second memory chips 120, respectively. For example, the second semiconductor chip stack CS2 may be included in the third channel CH3. The second chip pad 122 provided in the second memory chip 120 may be included in the third channel CH3. The second substrate pad 312B may exchange signals with the memory controller 210 through wiring provided on the package substrate 310.

The third semiconductor chip stack CS3 may be provided on the first semiconductor chip stack CS1. The third semiconductor chip stack CS3 may include one or more third memory chips 130. For example, as illustrated in FIG. 7, the third semiconductor chip stack CS3 may include three third memory chips 130. The plurality of third memory chips 130 may be stacked in steps.

One end of a third conductive wire 133 may be connected to the third chip pad 132 of the third memory chip 130. The other end of the third conductive wire 133 may be connected to the third substrate pad 312C provided on the package substrate 310. In addition, both ends of the third conductive wire 133 may be connected to third chip pads 132 of different third memory chips 130, respectively. For example, the third semiconductor chip stack CS3 may be included in the second channel CH2. The third chip pad 132 provided in the third memory chip 130 may be included in the second channel CH2. The third substrate pad 312C may exchange signals with the memory controller 210 through wiring provided on the package substrate 310.

In the semiconductor package 1A according to embodiments, the number of memory chips assigned to each channel may be unequal. For example, in the semiconductor package 1A, one first memory chip 110 may be included in the first channel CH1, three third memory chips 130 may be included in the second channel CH2, and six second memory chips 120 may be included in the third channel CH3. The first memory chip 110, the second memory chip 120, and the third memory chip 130 included in the plurality of non-volatile memories 100 are physically assigned to each channel.

Data requiring a relatively high-speed operation may use the first channel CH1, data requiring a relatively medium-speed operation may use the second channel CH2, and data requiring a relatively low-speed operation may use the third channel CH3. Accordingly, throughput per chip of the first memory chip 110, throughput per chip of the second memory chip 120, and throughput per chip of the third memory chip 130 may be different from one another. In addition, the throughput per chip may decrease in the order of the first memory chip 110, the second memory chip 120, and the third memory chip 130.

The memory controller 210 may determine whether data requires a high-speed operation to selectively distribute the data to the first channel CH1, the second channel CH2, or the third channel CH3. For example, because the throughput per chip of the first memory chip 110 included in the first channel CH1 is greater than the throughput per chip of the third memory chip 130 included in the second channel CH2 and the throughput per chip of the second memory chip 120 included in the third channel CH3, the memory controller 210 may assign the data requiring a high-speed operation to the first channel CH1.

That is, in the semiconductor package 1A according to embodiments, data processing efficiency may be improved through channels in which memory chips are unevenly arranged, and data may be effectively stored in and read from the plurality of non-volatile memories 100A. However, in the semiconductor package 1A according to an embodiment, the number of channels and the specific number of memory chips assigned to the channels are not limited by the previous example, except for the uneven arrangement of memory chips.

The semiconductor package 1A according to embodiments may include three semiconductor chip stacks CS1, CS2, and CS3, and the number of memory chips included in each semiconductor chip stack may vary. The sum of the number of first memory chips 110 included in the first semiconductor chip stack CS1 and the number of third memory chips 130 included in the third semiconductor chip stack CS3 may be less than the number of second memory chips 120 included in the second semiconductor chip stack CS2.

A first thickness T1 that is a vertical thickness of the memory controller 210 from the top surface of the package substrate 310 may be, for example, in a range of 1 to 2 times a second thickness T2. A difference between a vertical level of a third uppermost surface 130TS of the third semiconductor chip stack CS3 with respect to the top surface of the package substrate 310 and a vertical level of a second uppermost surface 120TS of the second semiconductor chip stack CS2 with respect to the top surface of the package substrate 310 may be less than the first thickness T1.

A vertical height of the semiconductor package 1A according to embodiments may be reduced through the uneven arrangement of memory chips. For example, as illustrated in FIG. 7, one first memory chip 110 and three third memory chips 130 may be located on the memory controller 210, and six second memory chips 120 may be located on the package substrate 310. As described above, when the vertical thicknesses of the first memory chip 110, the second memory chip 120, and the third memory chip 130 are substantially the same, and the first thickness T1 of the memory controller 210 is in a range of 1 to 2 times the second thickness T2 of the first memory chip 110, a difference in vertical level between the third uppermost surface 130TS and the second uppermost surface 120TS may be equal to the first thickness T1 or less. The third uppermost surface 130TS may refer to a top surface of the uppermost third memory chip 130 of the third memory chips 130 provided in the third semiconductor chip stack CS3.

As described above, a vertical thickness of the semiconductor package 1A according to embodiments may be reduced in a case in which the memory chips are unevenly distributed to the plurality of chip stacks compared to a case in which the same number of memory chips are included and the memory chips are evenly distributed to the plurality of chip stacks.

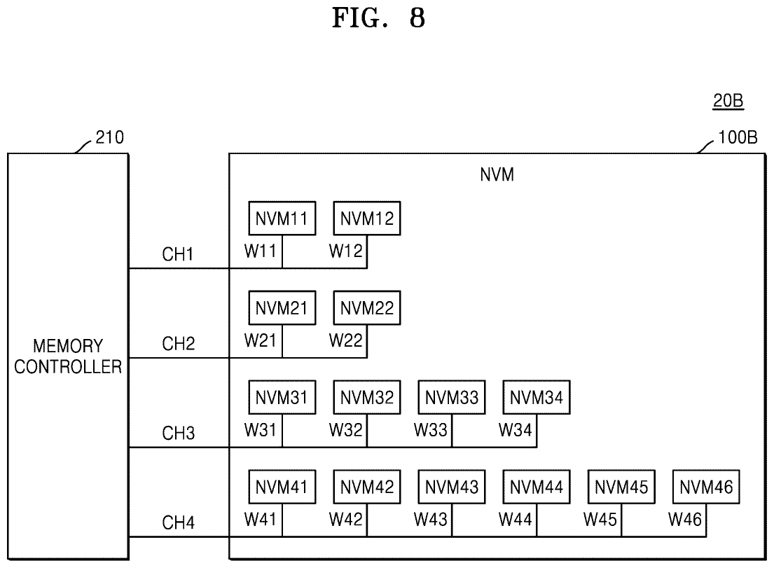

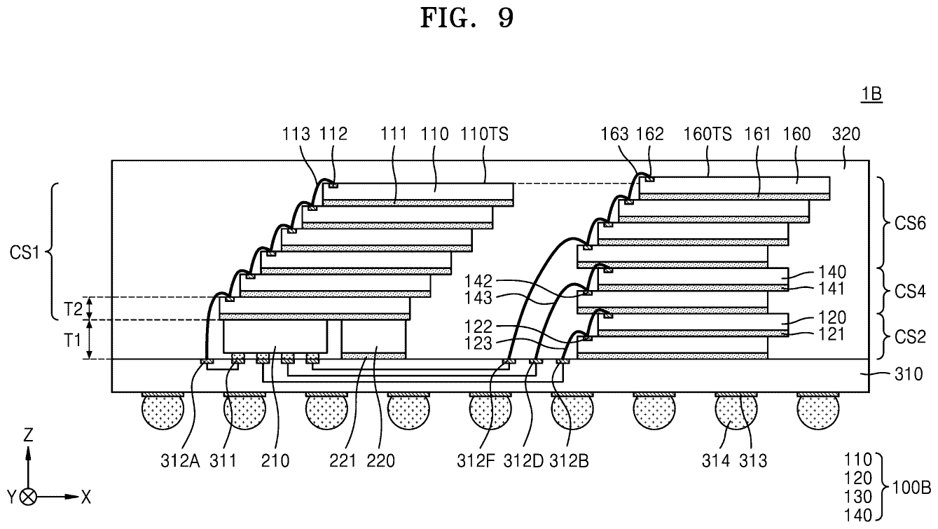

FIG. 8 is a block diagram illustrating a storage device 20B. FIG. 9 is a cross-sectional view illustrating a semiconductor package 1B according to embodiments. Content not separately described may be substantially the same as the above-described content.

The storage device 20B may include a memory controller 210 and non-volatile memory 100B. The storage device 20B may support a plurality of channels, and the non-volatile memory 100B and the memory controller 210 may be connected to each other through the plurality of channels. For example, the storage device 20B may include four channels CH1, CH2, CH3, and CH4, and the non-volatile memory 100B and the memory controller 210 may be connected to each other through the four channels CH1, CH2, CH3, and CH4. The storage device 20B may correspond to the semiconductor package 1B according to embodiments.

The non-volatile memory 100B may include a plurality of non-volatile memory devices. Each of the plurality of non-volatile memory devices may be connected to one of the plurality of channels through a corresponding way. For example, non-volatile memory devices NVM11 and NVM12 may be connected to the first channel CH1 through ways W11 and W12 respectively, non-volatile memory devices NVM21 and NVM22 may be connected to the second channel CH2 through ways W21 and W22 respectively, non-volatile memory devices NVM31, NVM32, NVM33, and NVM34 may be connected to the third channel CH3 through ways W31, W32, W33, and W34 respectively, and non-volatile memory devices NVM41, NVM42, NVM43, NVM44, NVM45, and NVM46 may be connected to the fourth channel CH4 through ways W41, W42, W43, W44, W45, and W46 respectively. In embodiments, each of the plurality of non-volatile memory devices may be implemented as an arbitrary memory unit that may operate according to an individual command from the memory controller 210.

The memory controller 210 may transmit and receive signals to and from the non-volatile memory 100B through the plurality of channels. For example, the memory controller 210 may transmit commands, addresses, and data to the non-volatile memory 100B through the channels CH1, CH2, CH3, and CH4, or may receive data from the non-volatile memory 100B.

The memory controller 210 may select one of the non-volatile memory devices connected to the corresponding channel through each channel and may transmit and receive signals to and from the selected non-volatile memory device. The memory controller 210 may transmit and receive signals to and from the non-volatile memory 100B in parallel through different channels. The memory controller 210 may control the overall operation of the non-volatile memory 100B, and each of the non-volatile memory devices NVM11 and NVM12, NVM21 and NVM22, and NVM31, NVM32, NVM33, and NVM34 may operate under control by the memory controller 210.

Referring to FIG. 9, the semiconductor package 1B may include a package substrate 310, a memory controller 210 provided on the package substrate 310, a spacer 220 provided on the package substrate 310 and laterally apart from the memory controller 210, a first semiconductor chip stack CS1 provided on the memory controller 210 and the spacer 220, a second semiconductor chip stack CS2 provided on the package substrate 310 and laterally apart from the first semiconductor chip stack CS1, a fourth semiconductor chip stack CS4 provided on the second semiconductor chip stack CS2, a sixth semiconductor chip stack CS6 provided on the fourth semiconductor chip stack CS4, and an encapsulant 320.

A first substrate pad 312A, a second substrate pad 312B, a fourth substrate pad 312D, a sixth substrate pad 312F, and a plurality of first substrate chip pads 311 may be provided on a top surface of the package substrate 310.

The first semiconductor chip stack CS1 may include one or more first memory chips 110. For example, as illustrated in FIG. 9, the first semiconductor chip stack CS1 may include six first memory chips 110. A first chip pad 112 may be provided on a top surface of the first memory chip 110. For example, the first semiconductor chip stack CS1 may be included in the fourth channel CH4. Each of the first memory chip 110, the first chip pad 112, the first conductive wire 113, and the first substrate pad 312A may correspond to part of the fourth channel CH4.

The second semiconductor chip stack CS2 may be provided on the package substrate 310 and laterally apart from the first semiconductor chip stack CS1 and the memory controller 210. The second semiconductor chip stack CS2 may include one or more second memory chips 120. For example, as illustrated in FIG. 9, the second semiconductor chip stack CS2 may include two second memory chips 120. For example, the second semiconductor chip stack CS2 may be included in the first channel CH1. Each of the second memory chip 120, the second chip pad 122, the second conductive wire 123, and the second substrate pad 312B may correspond to part of the first channel CH1.

The fourth semiconductor chip stack CS4 may be provided on the second semiconductor chip stack CS2. The fourth semiconductor chip stack CS4 may include one or more fourth memory chips 140. For example, as illustrated in FIG. 9, the fourth semiconductor chip stack CS4 may include two fourth memory chips 140. A fourth die adhesive film 141 may be provided on a bottom surface of the fourth memory chip 140. For example, the fourth semiconductor chip stack CS4 may be included in the second channel CH2. Each of the fourth memory chip 140, the fourth chip pad 142, the fourth conductive wire 143, and the fourth substrate pad 312D may correspond to part of the second channel CH2.

The sixth semiconductor chip stack CS6 may be provided on the fourth semiconductor chip stack CS4. The sixth semiconductor chip stack CS6 may include one or more sixth memory chips 160. For example, as illustrated in FIG. 9, the sixth semiconductor chip stack CS6 may include four sixth memory chips 160. A sixth die adhesive film 161 may be provided on a bottom surface of the sixth memory chip 160. For example, the sixth semiconductor chip stack CS6 may be included in the third channel CH3. Each of the sixth memory chip 160, the sixth chip pad 162, the sixth conductive wire 163, and the sixth substrate pad 312F may correspond to part of the third channel CH3.

In the semiconductor package 1B according to embodiments, the number of memory chips assigned to each channel may be partially unequal. For example, in the semiconductor package 1B, two second memory chips 120 may be included in the first channel CH1, two fourth memory chips 140 may be included in the second channel CH2, four sixth memory chips 160 may be included in the third channel CH3, and six first memory chips 110 may be included in the fourth channel CH4. The first memory chip 110, the second memory chip 120, the fourth memory chip 140, and the sixth memory chip 160 included in the plurality of non-volatile memories 100 are physically assigned to each channel.

Data requiring a relatively high-speed operation may use the first channel CH1 and the second channel CH2, data requiring a relatively medium-speed operation may use the third channel CH3, and data requiring a relatively low-speed operation may use the fourth channel CH4. Accordingly, the throughput per chip of the second memory chip 120 and the throughput per chip of the fourth memory chip 140 may be substantially the same, and the throughput per chip of the first memory chip 110, the throughput per chip of the second memory chip 120, and the throughput per chip of the sixth memory chip 160 may be different from one another. In addition, the throughput per chip may be greater in the order of the second memory chip 120, the sixth memory chip 160, and the first memory chip 110.

The memory controller 210 may determine whether data requires a high-speed operation to selectively distribute the data to the first channel CH1, the second channel CH2, the third channel CH3, or the fourth channel CH4. For example, because the throughput per chip of the second memory chip 120 included in the first channel CH1 is greater than the throughput per chip of the sixth memory chip 160 included in the third channel CH3 and the throughput per chip of the first memory chip 110 included in the fourth channel CH4, the memory controller 210 may assign the data requiring a high-speed operation to the first channel CH1. Alternatively, because the throughput per chip of the second memory chip 120 and the throughput per chip of the fourth memory chip 140 are substantially the same, the memory controller 210 may assign the data requiring a high-speed operation to the first channel CH1 and/or the second channel CH2.

That is, in the semiconductor package 1B according to embodiments, data processing efficiency may be improved through channels in which memory chips are unevenly arranged, and data may be effectively stored in and read from the plurality of non-volatile memories 100B. However, in the semiconductor package 1B according to an embodiment, the number of channels and the specific number of memory chips assigned to the channels are not limited by the previous example, except for the uneven arrangement of memory chips.

The semiconductor package 1B according to embodiments may include four semiconductor chip stacks CS1, CS2, CS4, and CS6, and the number of memory chips included in each semiconductor chip stack may vary. The number of first memory chips 110 included in the first semiconductor chip stack CS1 may be less than the sum of the number of second memory chips 120 included in the second semiconductor chip stack CS2, the number of fourth memory chips 140 included in the fourth semiconductor chip stack CS4, and the number of sixth memory chips 160 included in the sixth semiconductor chip stack CS6.

A first thickness T1 that is a vertical thickness of the memory controller 210 from the top surface of the package substrate 310 may be, for example, in a range of 1 to 2 times a second thickness T2. A difference between a vertical level of a first uppermost surface 110TS of the first semiconductor chip stack CS1 with respect to the top surface of the package substrate 310 and a vertical level of a sixth uppermost surface 160TS of the sixth semiconductor chip stack CS6 with respect to the top surface of the package substrate 310 may be less than the second thickness T2.

A vertical height of the semiconductor package 1B according to embodiments may be reduced through the uneven arrangement of memory chips. For example, as illustrated in FIG. 9, six first memory chips 110 may be located on the memory controller 210, and two second memory chips 120, four fourth memory chips 140, and six sixth memory chips 160 may be located on the package substrate 310. As described above, when the vertical thicknesses of the first memory chip 110, the second memory chip 120, the fourth memory chip 140, and the sixth memory chip 160 are substantially the same, and the first thickness T1 of the memory controller 210 is in a range of 1 to 2 times the second thickness T2 of the first memory chip 110, a difference in vertical level between the third uppermost surface 130TS and the sixth uppermost surface 160TS may be equal to the first thickness T1 or less. The sixth uppermost surface 160TS may refer to a top surface of the uppermost sixth memory chip 160 of the sixth memory chips 160 provided in the sixth semiconductor chip stack CS6.

As described above, a vertical thickness of the semiconductor package 1B according to embodiments may be reduced in a case in which the memory chips are unevenly distributed to the plurality of chip stacks compared to a case in which the same number of memory chips are included and the memory chips are evenly distributed to the plurality of chip stacks.

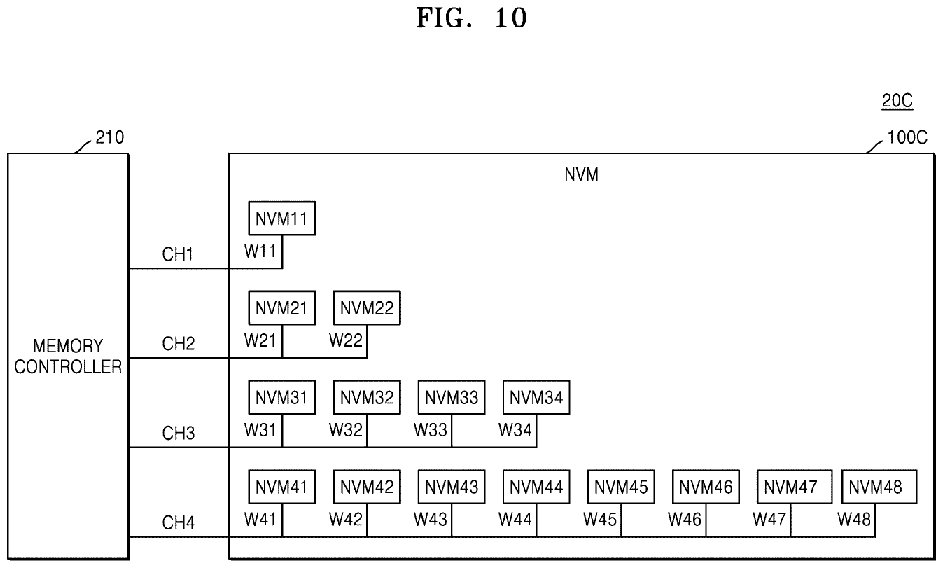

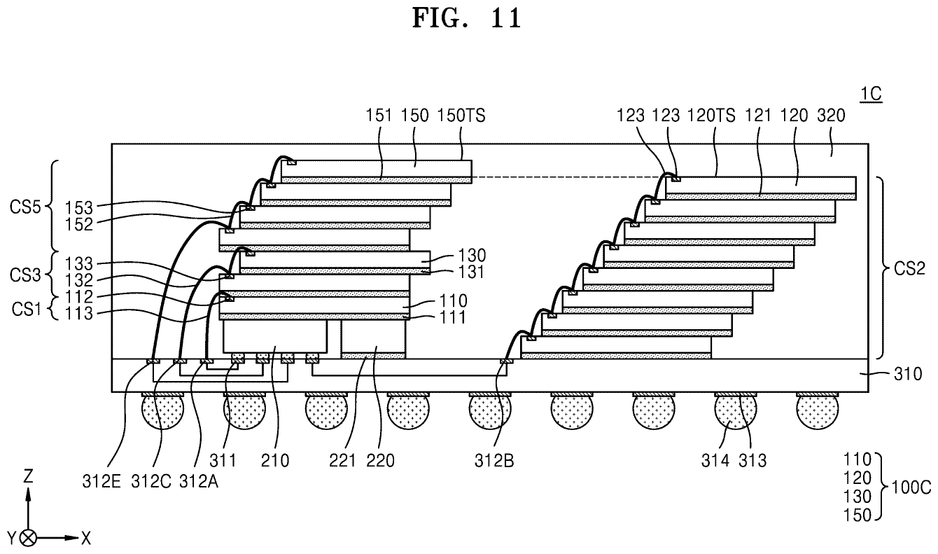

FIG. 10 is a block diagram illustrating a storage device 20C. FIG. 11 is a cross-sectional view illustrating a semiconductor package 1C according to embodiments. Content not separately described may be substantially the same as the above-described content.

Referring to FIG. 10, the storage device 20C may include a memory controller 210 and non-volatile memory 100C. The storage device 20C may include four channels CH1, CH2, CH3, and CH4, and the non-volatile memory 100B and the memory controller 210 may be connected to each other through the four channels CH1, CH2, CH3, and CH4. The storage device 20C may correspond to the semiconductor package 1C according to embodiments.

The non-volatile memory 100C may include a plurality of non-volatile memory devices. Each of the plurality of non-volatile memory devices may be connected to one of the plurality of channels through a corresponding way. For example, a non-volatile memory device NVM11 may be connected to the first channel CH1 through a way W11, non-volatile memory devices NVM21 and NVM22 may be connected to the second channel CH2 through ways W21 and W22 respectively, non-volatile memory devices NVM31, NVM32, NVM33, andNVM34 may be connected to the third channel CH3 through ways W31, W32, W33, and W34 respectively, and non-volatile memory devices NVM41, NVM42, NVM43, NVM44, NVM45, NVM46, NVM47, and NVM48 may be connected to the fourth channel CH4 through ways W41, W42, W43, W44, W45, W46, W47, and W48 respectively.

Referring to FIG. 11, the semiconductor package 1C may include a package substrate 310, a memory controller 210 provided on the package substrate 310, a spacer 220 provided on the package substrate 310 and laterally apart from the memory controller 210, a first semiconductor chip stack CS1 provided on the memory controller 210 and the spacer 220, a third semiconductor chip stack CS3 provided on the first semiconductor chip stack CS1, a fifth semiconductor chip stack CS5 provided on the third semiconductor chip stack CS3, a second semiconductor chip stack CS2 provided on the package substrate 310 and laterally apart from the first semiconductor chip stack CS1, and an encapsulant 320.

A first substrate pad 312A, a second substrate pad 312B, a third substrate pad 312C, a fifth substrate pad 312E, and a plurality of first substrate chip pads 311 may be provided on a top surface of the package substrate 310.

The first semiconductor chip stack CS1 may include one or more first memory chips 110. For example, as illustrated in FIG. 11, the first semiconductor chip stack CS1 may include one first memory chip 110. A first chip pad 112 may be provided on a top surface of the first memory chip 110. For example, the first semiconductor chip stack CS1 may be included in the first channel CH1. Each of the first memory chip 110, the first chip pad 112, the first conductive wire 113, and the first substrate pad 312A may correspond to part of the first channel CH1.

The second semiconductor chip stack CS2 may include one or more second memory chips 120. For example, as illustrated in FIG. 11, the second semiconductor chip stack CS2 may include eight second memory chips 120. For example, the second semiconductor chip stack CS2 may be included in the fourth channel CH4. Each of the second memory chip 120, the second chip pad 122, the second conductive wire 123, and the second substrate pad 312B may correspond to part of the fourth channel CH4.

The third semiconductor chip stack CS3 may include one or more third memory chips 130. For example, as illustrated in FIG. 11, the third semiconductor chip stack CS3 may include two third memory chips 130. A third die adhesive film 131 may be provided on a bottom surface of the third memory chip 130. For example, the third semiconductor chip stack CS3 may be included in the second channel CH2. Each of the third memory chip 130, the third chip pad 132, the third conductive wire 133, and the third substrate pad 312C may correspond to part of the second channel CH2.

The fifth semiconductor chip stack CS5 may include one or more fifth memory chips 150. For example, as illustrated in FIG. 11, the fifth semiconductor chip stack CS5 may include four fifth memory chips 150. A fifth die adhesive film 151 may be provided on a bottom surface of the fifth memory chip 150. For example, the fifth semiconductor chip stack CS5 may be included in the third channel CH3. Each of the fifth memory chip 150, the fifth chip pad 152, the fifth conductive wire 153, and the fifth substrate pad 312E may correspond to part of the third channel CH3.

In the semiconductor package 1C according to embodiments, the number of memory chips assigned to each channel may be partially unequal as described above. The first memory chip 110, the second memory chip 120, the fourth memory chip 140, and the sixth memory chip 160 included in the plurality of non-volatile memories 100 are physically assigned to each channel.

Data requiring a relatively high-speed operation may use the first channel CH1, data requiring a relatively medium-speed operation may use the second channel CH2 or the third channel CH3, and data requiring a relatively low-speed operation may use the fourth channel CH4. Even in the medium-speed operation, the throughput per chip of the third memory chip 130 included in the second channel CH2 may be greater than the throughput per chip of the fifth memory chip 150 included in the third channel CH3.

Because the number of memory chips included in each of the first to fourth channels CH1, CH2, CH3, and CH4 varies, the throughput per chip of the first memory chip 110, the throughput per chip of the second memory chip 120, the throughput per chip of the third memory chip 130, and the throughput per chip of the fifth memory chip 150 may be different from one another. In addition, the throughput per chip may be greater in the order of the first memory chip 110, the third memory chip 130, the fifth memory chip 150, and the second memory chip 120. The memory controller 210 may determine whether data requires a high-speed operation to selectively distribute the data to the first channel CH1, the second channel CH2, the third channel CH3, or the fourth channel CH4.

In the semiconductor package 1C according to embodiments, data processing efficiency may be improved through channels in which memory chips are unevenly arranged, and data may be effectively stored in and read from the plurality of non-volatile memories 100C. However, in the semiconductor package 1C according to an embodiment, the number of channels and the specific number of memory chips assigned to the channels are not limited by the previous example, except for the uneven arrangement of memory chips.

The semiconductor package 1C according to embodiments may include four semiconductor chip stacks CS1, CS2, CS3, and CS5, and the number of memory chips included in each semiconductor chip stack may vary. The number of second memory chips 120 included in the second semiconductor chip stack CS2 may be greater than the sum of the number of first memory chips 110 included in the first semiconductor chip stack CS1, the number of third memory chips 130 included in the third semiconductor chip stack CS3, and the number of fifth memory chips 150 included in the fifth semiconductor chip stack CS5.

A vertical height of the semiconductor package 1C according to embodiments may be reduced through the uneven arrangement of memory chips. For example, as illustrated in FIG. 11, seven memory chips, including first, third, and fifth memory chips 110, 130, and 150 may be located on the memory controller 210, and eight second memory chips 120 may be located on the package substrate 310. As described above, when the vertical thicknesses of the first, second, third, and fifth memory chips 110, 120, 130, and 150 are substantially the same, and the first thickness T1 of the memory controller 210 is in a range of 1 to 2 times the second thickness T2 of the first memory chip 110, a difference in vertical level between the fifth uppermost surface 150TS and the second uppermost surface 120TS may be equal to the second thickness T2 or less. The fifth uppermost surface 150TS may refer to a top surface of the uppermost fifth memory chip 150 of the fifth memory chips 150 provided in the fifth semiconductor chip stack CS5.

As described above, a vertical thickness of the semiconductor package 1C according to embodiments may be reduced in a case in which the memory chips are unevenly distributed to the plurality of chip stacks compared to a case in which the same number of memory chips are included and the memory chips are evenly distributed to the plurality of chip stacks.

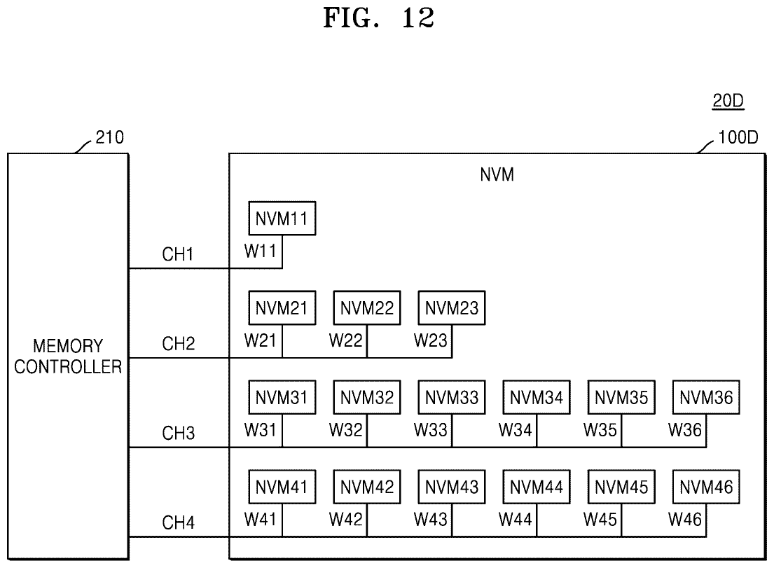

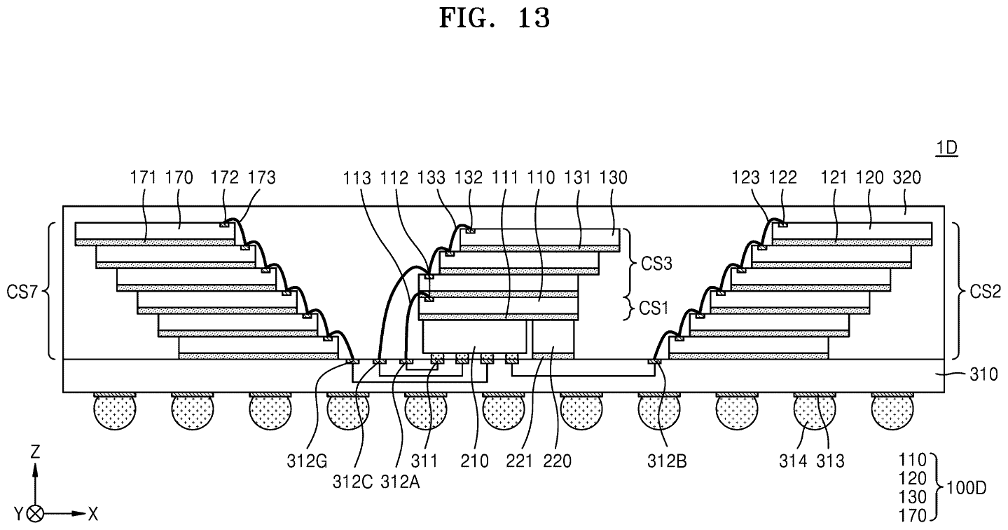

FIG. 12 is a block diagram illustrating a storage device 20D. FIG. 13 is a cross-sectional view illustrating a semiconductor package 1D according to embodiments. Content not separately described may be substantially the same as the above-described content.

Referring to FIG. 12, the storage device 20D may include a memory controller 210 and non-volatile memory 100D. For example, the storage device 20D may include four channels CH1, CH2, CH3, and CH4, and the non-volatile memory 100D and the memory controller 210 may be connected to each other through the four channels CH1, CH2, CH3, and CH4. The storage device 20D may correspond to the semiconductor package 1D according to embodiments.

For example, a non-volatile memory device NVM11 may be connected to the first channel CH1 through a way W11, non-volatile memory devices NVM21, NVM22, and NVM23 may be connected to the second channel CH2 through ways W21, W22, andW23 respectively, non-volatile memory devices NVM31, NVM32,, NVM33, NVM34, NVM35, and NVM36 may be connected to the third channel CH3 through ways W31, W32, W33, W34, W35, and W36 respectively, and non-volatile memory devices NVM41, NVM42, NVM43, NVM44, NVM45, and NVM46 may be connected to the fourth channel CH4 through ways W41, W42, W43, W44, W45, and W46 respectively.

Referring to FIG. 13, the semiconductor package 1D may include a package substrate 310, a memory controller 210 provided on the package substrate 310, a spacer 220 provided on the package substrate 310 and laterally apart from the memory controller 210, a first semiconductor chip stack CS1 provided on the memory controller 210 and the spacer 220, a third semiconductor chip stack CS3 provided on the first semiconductor chip stack CS1, a second semiconductor chip stack CS2 provided on the package substrate 310 and laterally apart from the first semiconductor chip stack CS1, a seventh semiconductor chip stack CS7 provided on the package substrate 310 and laterally apart from the first semiconductor chip stack CS1 and the second semiconductor chip stack CS2, and an encapsulant 320.

A first substrate pad 312A, a second substrate pad 312B, a third substrate pad 312C, a seventh substrate pad 312G, and a plurality of first substrate chip pads 311 may be provided on a top surface of the package substrate 310.

For example, as illustrated in FIG. 13, the first semiconductor chip stack CS1 may include one first memory chip 110. For example, the first semiconductor chip stack CS1 may be included in the first channel CH1. Each of the first memory chip 110, the first chip pad 112, the first conductive wire 113, and the first substrate pad 312A may correspond to part of the first channel CH1.

The second semiconductor chip stack CS2 may include six second memory chips 120. For example, the second semiconductor chip stack CS2 may be included in the third channel CH3. Each of the second memory chip 120, the second chip pad 122, the second conductive wire 123, and the second substrate pad 312B may correspond to part of the third channel CH3.

The third semiconductor chip stack CS3 may include three third memory chips 130. A third die adhesive film 131 may be provided on a bottom surface of the third memory chip 130. For example, the third semiconductor chip stack CS3 may be included in the second channel CH2. Each of the third memory chip 130, the third chip pad 132, the third conductive wire 133, and the third substrate pad 312C may correspond to part of the second channel CH2.

The seventh semiconductor chip stack CS7 may include one or more seventh memory chips 170. For example, as illustrated in FIG. 13, the seventh semiconductor chip stack CS7 may include six seventh memory chips 170. A seventh die adhesive film 171 may be provided on a bottom surface of the seventh memory chip 170. For example, the seventh semiconductor chip stack CS7 may be included in the fourth channel CH4. Each of the seventh memory chip 170, a seventh chip pad 172, a seventh conductive wire 173, and the seventh substrate pad 312G may correspond to part of the fourth channel CH4.

In the semiconductor package 1D according to embodiments, the number of memory chips assigned to each channel may be partially unequal as described above. The first memory chip 110, the second memory chip 120, the third memory chip 130, and the seventh memory chip 170 included in the plurality of non-volatile memories 100 are physically assigned to each channel.

Data requiring a relatively high-speed operation may use the first channel CH1, data requiring a relatively medium-speed operation may use the second channel CH2, and data requiring a relatively low-speed operation may use the third channel CH3 and/or the fourth channel CH4.

Because the number of memory chips included in each of the first to fourth channels CH1, CH2, CH3, and CH4 at least partially varies, the throughput per chip of the first memory chip 110, the throughput per chip of the second memory chip 120, and the throughput per chip of the third memory chip 130 may be different from one another. The throughput per chip of the seventh memory chip 170 may be substantially the same as the throughput per chip of the second memory chip 120. In addition, the throughput per chip may be greater in the order of the first memory chip 110, the third memory chip 130, and the second memory chip 120. The memory controller 210 may determine whether data requires a high-speed operation to selectively distribute the data to the first channel CH1, the second channel CH2, the third channel CH3, or the fourth channel CH4.

The semiconductor package 1D according to embodiments may include four semiconductor chip stacks CS1, CS2, CS3, and CS7, and the number of memory chips included in each semiconductor chip stack may at least partially vary. The number of second memory chips 120 included in the second semiconductor chip stack CS2 may be greater than the sum of the number of first memory chips 110 included in the first semiconductor chip stack CS1 and the number of third memory chips 130 included in the third semiconductor chip stack CS3. The number of second memory chips 120 included in the second semiconductor chip stack CS2 may be the same as the number of seventh memory chips 170 included in the seventh semiconductor chip stack CS7.

A vertical height of the semiconductor package 1D according to embodiments may be reduced through the uneven arrangement of memory chips. For example, as illustrated in FIG. 13, four memory chips including first and third memory chips 110 and 130 may be located on the memory controller 210, and six second memory chips 120 and six seventh memory chips 170 may be located on the package substrate 310. As described above, a vertical thickness of the semiconductor package 1D according to embodiments may be reduced in a case in which the memory chips are unevenly distributed to the plurality of chip stacks compared to a case in which the same number of memory chips are included and the memory chips are evenly distributed to the plurality of chip stacks.

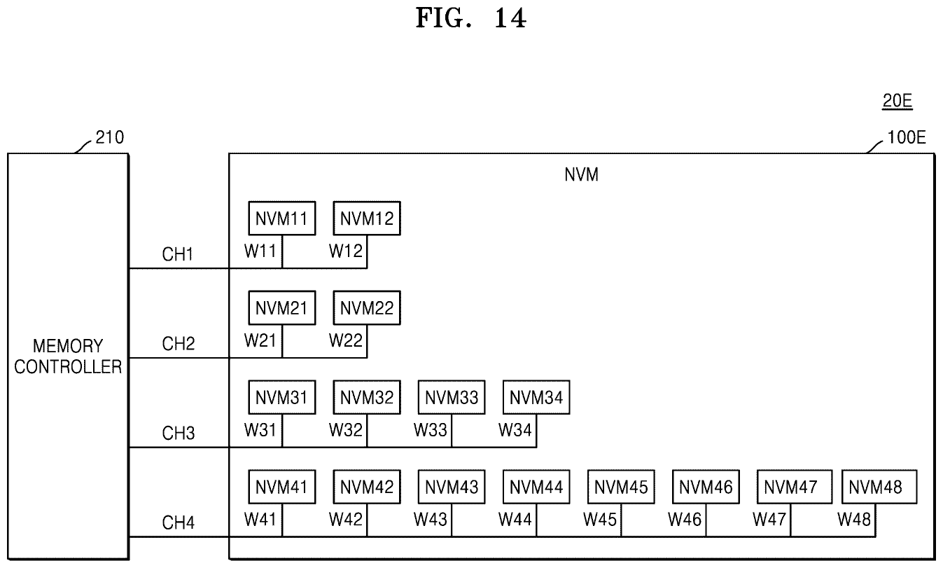

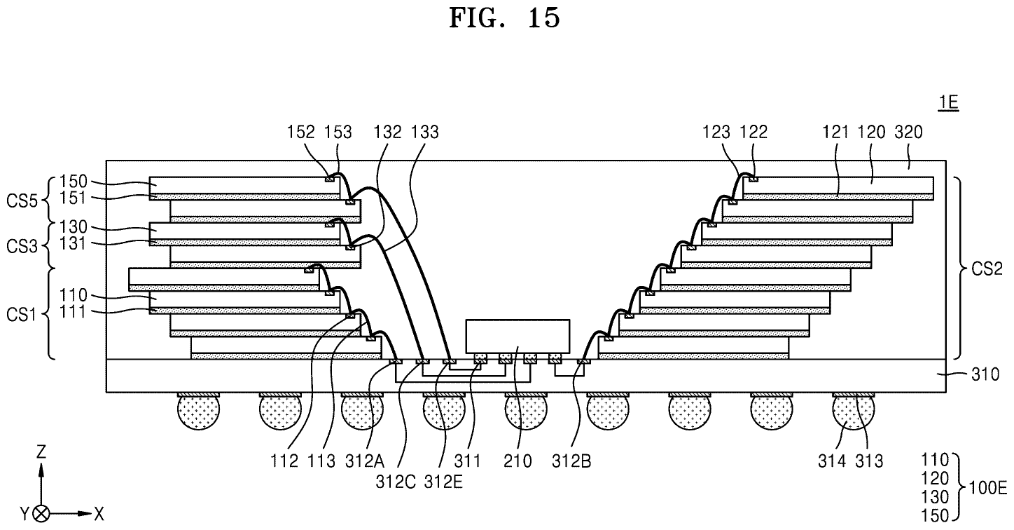

FIG. 14 is a block diagram illustrating a storage device 20E. FIG. 15 is a cross-sectional view illustrating a semiconductor package 1E according to embodiments. Content not separately described may be substantially the same as the above-described content.

Referring to FIG. 12, the storage device 20D may include the memory controller 210 and the non-volatile memory 100D. The storage device 20D may include four channels CH1, CH2, CH3, and CH4. For example, non-volatile memory devices NVM11 and NVM12 may be connected to the first channel CH1 through ways W11 and W12, non-volatile memory devices NVM21 and NVM22 may be connected to the second channel CH2 through ways W21 and W22, non-volatile memory devices NVM31 to NVM34 may be connected to the third channel CH3 through ways W31 to W34, and non-volatile memory devices NVM41 to NVM48 may be connected to the fourth channel CH4 through ways W41 to W48.

Referring to FIG. 15, the semiconductor package 1E may include a package substrate 310, a memory controller 210 provided on the package substrate 310, a first semiconductor chip stack CS1 provided on the package substrate 310 and laterally apart from the memory controller 210, a third semiconductor chip stack CS3 provided on the first semiconductor chip stack CS1, a fifth semiconductor chip stack CS5 provided on the third semiconductor chip stack CS3, a second semiconductor chip stack CS2 provided on the package substrate 310 and laterally apart from the first semiconductor chip stack CS1, and an encapsulant 320.

A first substrate pad 312A, a second substrate pad 312B, a third substrate pad 312C, a fifth substrate pad 312E, and a plurality of first substrate chip pads 311 may be provided on a top surface of the package substrate 310.

For example, as illustrated in FIG. 15, the first semiconductor chip stack CS1 may include four first memory chips 110. For example, the first semiconductor chip stack CS1 may be included in the third channel CH3. Each of the first memory chip 110, the first chip pad 112, the first conductive wire 113, and the first substrate pad 312A may correspond to part of the third channel CH3.

The second semiconductor chip stack CS2 may include eight second memory chips 120. For example, the second semiconductor chip stack CS2 may be included in the fourth channel CH4. Each of the second memory chip 120, the second chip pad 122, the second conductive wire 123, and the second substrate pad 312B may correspond to part of the fourth channel CH4.

The third semiconductor chip stack CS3 may include two third memory chips 130. For example, the third semiconductor chip stack CS3 may be included in the first channel CH1. Each of the third memory chip 130, the third chip pad 132, the third conductive wire 133, and the third substrate pad 312C may correspond to part of the first channel CH1.

The fifth semiconductor chip stack CS5 may include two fifth memory chips 150. For example, the fifth semiconductor chip stack CS5 may be included in the second channel CH2. Each of the third memory chip 130, the third chip pad 132, the third conductive wire 133, and the third substrate pad 312C may correspond to part of the second channel CH2.

In the semiconductor package 1E according to embodiments, the number of memory chips assigned to each channel may be partially unequal as described above. Because the number of memory chips included in each of the first to fourth channels CH1, CH2, CH3, and CH4 at least partially varies, the throughput per chip of the first memory chip 110, the throughput per chip of the second memory chip 120, and the throughput per chip of the third memory chip 130 may be different from one another. The throughput per chip of the third memory chip 130 may be substantially the same as the throughput per chip of the fifth memory chip 150.

That is, in the semiconductor package 1E according to embodiments, data processing efficiency may be improved through channels in which memory chips are unevenly arranged, and data may be effectively stored in and read from the plurality of non-volatile memories 100E. However, in the semiconductor package 1E according to an embodiment, the number of channels and the specific number of memory chips assigned to the channels are not limited by the previous example, except for the uneven arrangement of memory chips.

The semiconductor package 1E according to embodiments may include four semiconductor chip stacks CS1, CS2, CS3, and CS5, and the number of memory chips included in each semiconductor chip stack may at least partially vary. The number of second memory chips 120 included in the second semiconductor chip stack CS2 may be equal to the sum of the number of first memory chips 110 included in the first semiconductor chip stack CS1, the number of third memory chips 130 included in the third semiconductor chip stack CS3, and the number of fifth memory chips 150 included in the fifth semiconductor chip stack CS5. A vertical height of the semiconductor package 1E according to embodiments may be reduced by controlling a height of the uppermost surface of the semiconductor chip stack through the uneven arrangement of memory chips.

While the inventive concept has been particularly shown and described with reference to embodiments thereof, it will be understood that various changes in form and details may be made therein without departing from the scope of the following claims.

What is claimed is:

1. A semiconductor package comprising:
a package substrate;
a memory controller on the package substrate and comprising a plurality of channels;
a first semiconductor chip stack on the memory controller and comprising one or more first memory chips;
a second semiconductor chip stack on the package substrate, spaced apart from the first semiconductor chip stack, and comprising one or more second memory chips;
a first substrate pad on a top surface of the package substrate, electrically connected to the one or more first memory chips, and associated with a first channel of the plurality of channels; and
a second substrate pad on a top surface of the package substrate, electrically connected to the one or more second memory chips, and associated with a second channel of the plurality of channels,
wherein a number of the one or more first memory chips in the first semiconductor chip stack is different from a number of the one or more second memory chips in the second semiconductor chip stack.

2. The semiconductor package of claim 1, wherein the number of the one or more first memory chips in the first semiconductor chip stack is less than the number of the one or more second memory chips in the second semiconductor chip stack.

3. The semiconductor package of claim 1, wherein a difference between a first distance between an uppermost surface of the first semiconductor chip stack and the package substrate and a second distance between an uppermost surface of the second semiconductor chip stack and the package substrate is less than a thickness of a first memory chip of the one or more first memory chips in a direction perpendicular to an upper surface of the package substrate.

4. The semiconductor package of claim 1, wherein a thickness of the memory controller is in a range of 1 to 2 times a thickness of a first memory chip of the one or more first memory chips.

5. The semiconductor package of claim 1, wherein the first semiconductor chip stack is exclusively associated with the first channel,
wherein the second semiconductor chip stack is exclusively associated with the second channel.

6. The semiconductor package of claim 1, wherein the number of first memory chips in the first semiconductor chip stack is less than the number of second memory chips in the second semiconductor chip stack, and
wherein throughput of a memory chip of the one or more first memory chips is greater than throughput of a memory chip of the one or more second memory chips.

7. The semiconductor package of claim 1, wherein the memory controller supports a zoned universal flash storage (ZUFS) interface.

8. The semiconductor package of claim 1, wherein a first memory chip of the one or more first memory chips and a second memory chip of the one or more second memory chips comprise non-volatile memory chips.

9. The semiconductor package of claim 1, further comprising:
a third semiconductor chip stack on the first semiconductor chip stack, the third semiconductor chip stack comprising one or more third memory chips; and
a third substrate pad electrically connected to the third semiconductor chip stack, on a top surface of the package substrate, and associated with a third channel of the plurality of channels,
wherein a number of the one or more third memory chips in the third semiconductor chip stack is less than the number of the one or more second memory chips in the second semiconductor chip stack.

10. The semiconductor package of claim 9, wherein the number of the one or more first memory chips in the first semiconductor chip stack, the number of the one or more second memory chips in the second semiconductor chip stack, and the number of the one or more third memory chips in the third semiconductor chip stack are different from one another,
wherein the number of the one or more second memory chips in the second semiconductor chip stack is greater than a sum of the number of the one or more first memory chips in the first semiconductor chip stack and the number of the one or more third memory chips in the third semiconductor chip stack, and
wherein throughput of a memory chip of the one or more third memory chips is smallest among throughput of a memory chip of the one or more first memory chips, throughput of a memory chip of the one or more second memory chips, and throughput of the memory chip of the one or more third memory chips.

11. The semiconductor package of claim 1, further comprising:
a fourth semiconductor chip stack on the first semiconductor chip stack and comprising one or more fourth memory chips;
a sixth semiconductor chip stack on the fourth semiconductor chip stack and comprising one or more sixth memory chips;
a fourth substrate pad electrically connected to the one or more fourth memory chips, on a top surface of the package substrate, and associated with a third channel of the plurality of channels; and
a sixth substrate pad electrically connected to the one or more sixth memory chips, on the top surface of the package substrate, and associated with a fourth channel of the plurality of channels,
wherein a number of the one or more first memory chips in the first semiconductor chip stack is less than a sum of a number of the one or more second memory chips, a number of the one or more fourth memory chips, and a number of the one or more sixth memory chips, and
wherein a difference between a first distance between an uppermost surface of the first semiconductor chip stack and the package substrate and a second distance between an uppermost surface of the sixth semiconductor chip stack and the package substrate is less than a thickness of a first memory chip of the one or more first memory chips in a direction perpendicular to an upper surface of the package substrate.

12. The semiconductor package of claim 11, wherein throughput of a memory chip of the one or more first memory chips is less than throughput of a memory chip of the one or more second memory chips, throughput of a memory chip of the one or more fourth memory chips, and throughput of a memory chip of the one or more sixth memory chips.

13. The semiconductor package of claim 1, further comprising:
a third semiconductor chip stack on the first semiconductor chip stack and comprising one or more third memory chips;
a fifth semiconductor chip stack on the third semiconductor chip stack and comprising one or more fifth memory chips;
a third substrate pad electrically connected to the third semiconductor chip stack, on a top surface of the package substrate, and associated with a third channel of the plurality of channels; and
a fifth substrate pad electrically connected to the fifth semiconductor chip stack, on the top surface of the package substrate, and associated with a fourth channel of the plurality of channels,
wherein a number of the one or more second memory chips in the second semiconductor chip stack is less than a sum of the number of the one or more first memory chips, the number of the one or more third memory chips, and the number of the one or more fifth memory chips, and
wherein a difference between a first distance between an uppermost surface of the first semiconductor chip stack from the package substrate and a second distance between an uppermost surface of the fifth semiconductor chip stack from the package substrate is less than a thickness of a first memory chip of the one or more first memory chips in a direction perpendicular to an upper surface of the package substrate.

14. The semiconductor package of claim 1, further comprising:
a third semiconductor chip stack on the first semiconductor chip stack and comprising one or more third memory chips;
a seventh semiconductor chip stack on the package substrate, spaced apart from the first semiconductor chip stack, and comprising one or more seventh memory chips;
a third substrate pad electrically connected to the third semiconductor chip stack, on a top surface of the package substrate, and associated with a third channel of the plurality of channels; and
a seventh substrate pad electrically connected to the seventh semiconductor chip stack, on the top surface of the package substrate, and associated with a fourth channel of the plurality of channels,
wherein each of a difference between a first distance between an uppermost surface of the third semiconductor chip stack from the package substrate and a second distance between an uppermost surface of the second semiconductor chip stack from the package substrate, and a difference between a third distance between an uppermost surface of the third semiconductor chip stack from the package substrate and a fourth distance between an uppermost surface of the seventh semiconductor chip stack from the package substrate is less than a thickness of a first memory chip of the one or more first memory chips in a direction perpendicular to an upper surface of the package substrate.

15. A semiconductor package comprising:
a package substrate;
a memory controller on the package substrate and comprising a plurality of channels;
a plurality of semiconductor chip stacks on the package substrate, spaced apart from the memory controller, and comprising a first semiconductor chip stack and a third semiconductor chip stack;
a second semiconductor chip stack on the package substrate, spaced apart from the plurality of semiconductor chip stacks and the memory controller;
a first substrate pad on a top surface of the package substrate, electrically connected to the one or more first memory chips, and associated with a first channel of the plurality of channels;
a second substrate pad on a top surface of the package substrate, electrically connected to the one or more second memory chips, and associated with a second channel of the plurality of channels; and
a third substrate pad on a top surface of the package substrate, electrically connected to the one or more third memory chips, and associated with a third channel of the plurality of channels,
wherein the first semiconductor chip stack comprises one or more first memory chips, the second semiconductor chip stack comprises one or more second memory chips, and the third semiconductor chip stack comprises one or more third memory chips, and
wherein a number of the one or more first memory chips, a number of the one or more second memory chips, and a number of the one or more third memory chips are different from one another, and the number of the one or more second memory chips is greater than a sum of the number of the one or more first memory chips and the number of the one or more third memory chips.

16. The semiconductor package of claim 15, wherein a distance between an uppermost surface of the plurality of semiconductor chip stacks and the package substrate is same as a distance between an uppermost surface of the second semiconductor chip stack and the package substrate.

17. The semiconductor package of claim 15, wherein throughput of a memory chip of the one or more first memory chips, throughput of a memory chip of the one or more second memory chips, and throughput of a memory chip of the one or more third memory chips are different from one another.

18. A semiconductor package comprising:
a package substrate;
a memory controller on the package substrate and comprising a plurality of channels;
a first semiconductor chip stack on the package substrate comprising one or more first memory chips;
a second semiconductor chip stack on the package substrate comprising one or more second memory chips;
a third semiconductor chip stack on the package substrate comprising one or more third memory chips;
a first substrate pad on a top surface of the package substrate, electrically connected to the first semiconductor chip stack, and associated with a first channel of the plurality of channels;
a second substrate pad on a top surface of the package substrate, electrically connected to the second semiconductor chip stack, and associated with a second channel of the plurality of channels; and
a third substrate pad on a top surface of the package substrate, electrically connected to the third semiconductor chip stack, and associated with a third channel of the plurality of channels,
wherein a number of the one or more second memory chips in the second semiconductor chip stack is greater than a number of the one or more first memory chips in the first semiconductor chip stack, and a number of the one or more third memory chips in the third semiconductor chip stack is greater than the number of the one or more second memory chips in the second semiconductor chip stack, and
wherein a throughput of a memory chip of the one or more first memory chips is greater than a throughput of a memory chip of the one or more second memory chips which is greater than throughput per chip of a memory chip of the one or more third memory chips.

19. The semiconductor package of claim 18, wherein the first semiconductor chip stack is exclusively associated with the first channel, the second semiconductor chip stack is exclusively associated with the second channel, and the third semiconductor chip stack is exclusively associated with the third channel.

20. The semiconductor package of claim 18, wherein the memory controller supports a zoned universal flash storage (ZUFS).
